(19) United States
(12) Patent Application Publication
(10) Pub. No.: US 2008/0237894 A1
(43) Pub. Date: Oct. 2, 2008

(54) INTEGRATED CIRCUIT PACKAGE AND METHOD FOR THE SAME

(76) Inventors: Ki-Hyun KIM, Suwon-si (KR); Jin Yu, Yuseong-gu (KR); Young-Min Lee, Yongin-si (KR); June-Hyeon Ahn, Suwon-si (KR); Ho-Seong Seo, Suwon-si (KR); Youn-Ho Choi, Seoul (KR); Yong Jung, Yuseong-gu (KR); Taek-Yeong Lee, Seoul (KR); Young-Kun Jee, Yuseong-gu (KR)

Correspondence Address: CHA & REITER, LLC, 210 ROUTE 4 EAST STE 103, PARAMUS, NJ, 07652, US

(21) Appl. No.: 12/054,562

(22) Filed: Mar. 25, 2008

(30) Foreign Application Priority Data
Mar. 26, 2007 (KR) 2007-29440

(51) Int. Cl. H01L 23/48; H01L 21/58

(52) U.S. Cl. 257/783; 438/118; 257/E23.01; 257/E21.505

(57) ABSTRACT

Disclosed are an integrated circuit chip package and a method of connecting an integrated circuit chip and an attachment subject to each other while interposing an adhesive therebetween. The connection between integrated circuit chip and the attachment subject stress often leads to component failure and the addition of an interface layer with a similar thermal expansion coefficient improves reliability. The method may include applying the adhesive on the attachment subject, forming an interface layer between the integrated circuit chip and the adhesive wherein the interface layer has a thermal expansion coefficient similar to a thermal expansion coefficient of the integrated circuit chip. By connecting an integrated circuit chip and the attachment subject to each other by an adhesive via the interface layer, the generation of delamination is minimized and reliability is improved.

### CLAIM OF PRIORITY

This application claims the benefit of priority under 35 U.S.C. §119(a) from an application entitled “Integrated circuit package and method for the same” filed in the Korean Intellectual Property Office on Mar. 26, 2007 and assigned Serial No. 2007-29440, the contents of which are hereby incorporated by reference in its entirety.

### BACKGROUND OF THE INVENTION

1. Field of the Invention

The present invention relates to an integrated circuit package and a method for the same. More particularly, the present invention relates to a method of attachment between an integrated circuit chip and an attachment subject and a structure using the same.

2. Description of the Related Art

An integrated circuit package is a structure having an integrated circuit chip mounted on a substrate (an attachment subject), e.g. printed circuit substrate, etc. In an integrated circuit package, various functions that constitute a system, such as a logic, a memory, and a device, etc., are integrated in a single structure.

A typical integrated circuit package includes a printed circuit board (PCB), which is typically used as a substrate. The PCB includes an insulating substrate having an electric circuit formed thereon by copper coating or copper plating, and electronic components, such as an integrated circuit chip can be mounted on the printed circuit board.

A chip mounting process is used to mount an embedded IC and/or a stacked IC, etc. onto a PCB. In order to raise the whole degree of integration of an electric device in a system level, a three dimensional mounting method for mounting a chip in a direction of a Z axis has become a popular chip mounting process that increases the usable area of the PCB and leads to improved performance. This mounting method is different from the mounting method for mounting a chip in a direction of a X-Y axis as the third dimension must be taken into consideration in both design and implementation.

FIG. 1 is a view illustrating an example of a construction of an integrated circuit package according to the conventional art. Referring to FIG. 1, in the conventional technique for mounting an integrated circuit chip on a printed circuit substrate 101 has a solder mask 102 is deposited on the printed circuit substrate. An epoxy material 103 is disposed on the solder mask 102 and only half-cured. Next, an integrated circuit chip 104 is stacked on the epoxy material 103, and then the epoxy material 103 is completely cured. Therefore, the integrated circuit chip and the printed circuit substrate can be physically and chemically connected with each other.

In FIG. 1, items 105 and 106 are polyimide layer and encapsulation, respectively, which are typically used for protecting integrated circuit chip 104.

However, the epoxy material, which is used for bonding the integrated circuit chip and the printed circuit substrate with each other, has a coefficient of thermal expansion (CTE) of about 80˜140 ppm/° C. This thermal expansion coefficient shows a remarkable difference compared with a thermal expansion coefficient of ˜2.7 ppm/° C. of silicon (Si), which is mainly used for a substrate material of an integrated circuit chip. Accordingly, a high degree of mechanical stress is generated in an interface between the integrated circuit chip and the printed circuit substrate because of change of heat radiated in operation of a device or hygroscopicity thereof.

FIG. 2 shows that delamination is generated in an interface between a silicon chip and epoxy due to the low adhesive strengths of silicon and epoxy. As a result, the interconnection lines of the integrated circuit chip can be under a high degree of stress (e.g. mechanical and/or thermal), thereby causing electrical failure of the device.

### SUMMARY OF THE INVENTION

Accordingly, the present invention has been made in part to solve at least some of the above-mentioned problems occurring in the prior art, as well as provide additional advantages. The present invention provides an integrated circuit package and a method for construction, which can improve the adhesive strength between an integrated circuit chip and an attachment subject, and minimize the amount of stress in a contact interface of the integrated circuit chip and the attachment subject.

In accordance with an exemplary aspect of the present invention, there is provided an integrated circuit package including: an attachment subject; an integrated circuit chip attached to the attachment subject by an adhesive; and an interface layer disposed between the integrated circuit chip and the adhesive and preferably having a thermal expansion coefficient similar to a thermal expansion coefficient of the integrated circuit chip.

According to the present invention, the adhesives may comprise, for example, an adhesive epoxy, the integrated circuit chip may comprise, for example, a silicon chip, and the attachment subject may comprise, for example, a printed circuit substrate. Furthermore, the interface layer typically has a thermal expansion coefficient of a range of about 3˜5 ppm/° C., and the interface layer may comprise, for example, a material typically having a property of a Young's modulus of a range of about 3˜9 Gpa, a Poisson's ratio of a typical range of about 0.25˜0.4, and a glass temperature typically ranging from about 240° C. 260° C.

Also, according to the present invention, the interface layer may comprise, for example, a material including but not limited to at least one of Polyimide, Acrylinitrilebutadienestyrene (ABS), Benzocyclobutene (BCB), Polystyrene (PS), and Polymethylmethacrylate (PMMA).

In accordance with another exemplary aspect of the present invention, there is provided a method of connecting an integrated circuit chip and an attachment subject to each other while interposing an adhesive between the integrated circuit chip and the attachment subject, the method including the steps of: applying the adhesive on the attachment subject; and forming an interface layer between the integrated circuit chip and the adhesive, the interface layer preferable having a thermal expansion coefficient similar to a thermal expansion coefficient of the integrated circuit chip.

In accordance with the above-mentioned example of a method according to the present invention, the integrated circuit chip may comprise, for example, a silicon chip, the attachment subject may comprise, for example, a printed circuit substrate, and the adhesive may comprise, for example, adhesive epoxy.

Also, the interface layer preferably has a thermal expansion coefficient of a range of about 3˜55 ppm/° C.

### BRIEF DESCRIPTION OF THE DRAWINGS

The above and other exemplary aspects, features and advantages of the present invention will be more apparent from the following detailed description taken in conjunction with the accompanying drawings, in which:

FIG. 1 is a view illustrating an example of a construction of an integrated circuit package according to the conventional art;

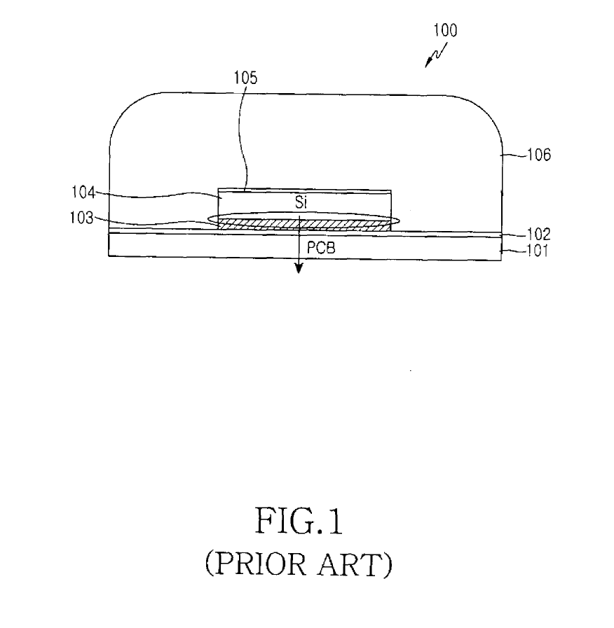

FIG. 2 is a view illustrating delamination generated in an interface between a silicon chip and epoxy; and

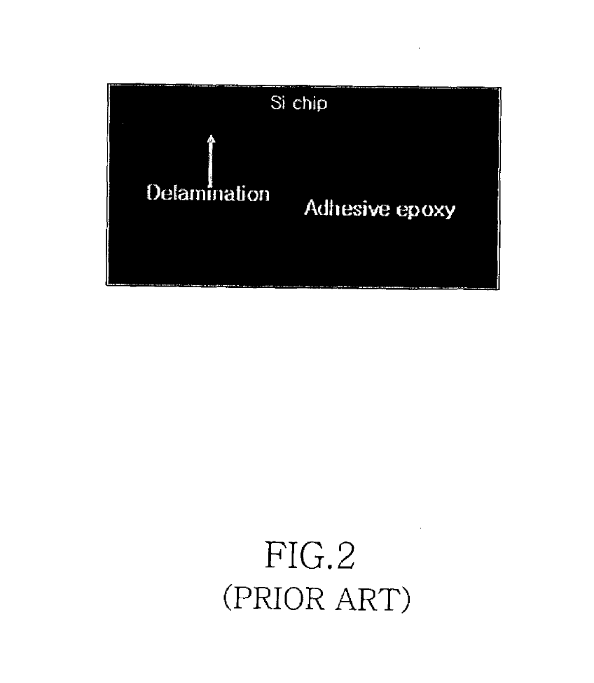

FIG. 3 is a view illustrating an example of a construction of an integrated circuit package according to an exemplary embodiment of the present invention.

### DETAILED DESCRIPTION OF THE INVENTION

Hereinafter, exemplary and preferred embodiments of the present invention will be described with reference to the accompanying drawings. A person of ordinary skill in the art understands that the present invention is not limited to the following description and drawings, as such examples have been provided for illustrative purposes, and do not limit the invention to the examples shown and described. Further, in the following description of the present invention, a detailed description of known functions and configurations incorporated herein may be omitted when such known functions and configurations would obscure appreciation of the subject matter of the present invention by a person of ordinary skill in the art.

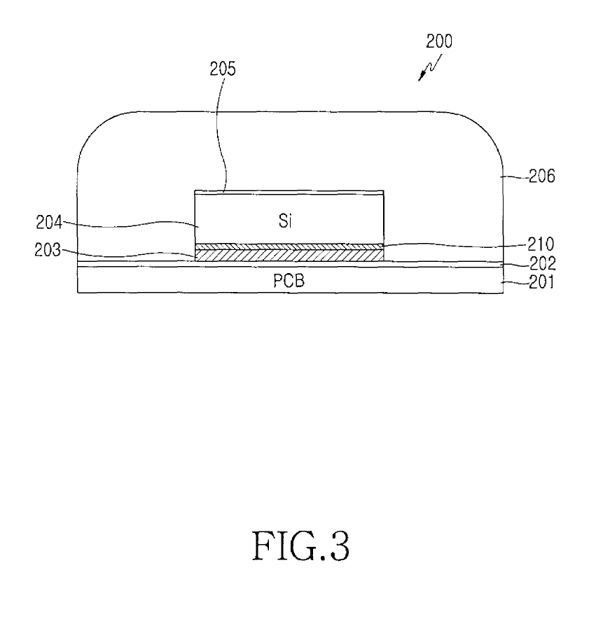

FIG. 3 is a view illustrating an example of a construction of an integrated circuit package according to one exemplary embodiment of the present invention. In the example, an interface layer of the present invention is formed in an integrated circuit package having an integrated circuit (in this case a silicon chip) and an attachment subject (in this case a printed circuit substrate) that are connected with each other by an adhesive (in this case an epoxy).

Referring to FIG. 3, the integrated circuit package 200 according to this example of the present invention includes a substrate 201 having a printed circuit pattern formed thereon, a solder mask 202 formed on the substrate 201 having a printed circuit pattern formed thereon, a silicon chip 204 having a protecting layer 205 formed on an upper part thereof an epoxy adhesive layer 203 formed between the silicon chip 204 and the solder mask 202, an interface layer 210 formed between the silicon chip 204 and the epoxy adhesive layer 203, and an encapsulation material 206 sealing a surface of the substrate 201 having the silicon chip 204 formed thereon.

Still referring to FIG. 3, the interface layer 210 is disposed between the silicon chip 204 and the epoxy adhesive layer 203 so as to minimize mechanical stress caused by thermal hysteresis. The interface layer may be comprised of a material typically having a thermal expansion coefficient (a range of about 3˜55 ppm/° C.) similar to the thermal expansion coefficient of a silicon chip (about ˜2.7 ppm/° C.) or a material having properties similar to the properties of the silicon chip. In the present example, the material having properties similar to the properties of the silicon chip refers to a material having the Young's modulus in a typical range of about 3˜9 Gpa, the Poisson's ratio in a typical range of about 0.25˜0.4, and the glass temperature in the typical range of about 240° C.˜260° C. Polyimide, Acrylinitrilebutadienestyrene (ABS), Benzocyclobutene (BCB), Polystyrene (PS), Polymethylmethacrylate (PMMA), etc. are some non-limiting examples of the material satisfying the corresponding condition, and it should be understood by a person of ordinary skill in the art that the present invention the interface layer can be made of other materials than the above exemplary materials. The similarities of the properties do not have to match. According to the present invention, the more similar the properties are to each other used in the package, the less of a problem that stresses caused by differences in the values can cause component failure. The thickness of the interface layer 210 and the pattern-shape thereof are variable according to the size of the integrated circuit chip, and polyimide is stably deposited on the interface layer 210 in view of stress when the polyimide has a thickness of about 2˜7 μm.

The interface layer 210 may be formed in such a manner that a spin coating is formed on a real surface of the silicon chip 204, or the polymer material is directly stacked.

Still referring to FIG. 3, a connecting scheme using a spin coating will now be described. First, a polyimide is applied on a lower surface of the silicon chip 204 by spin coating. Then, the lower surface of silicon chip 204 comes into contact with the printed circuit substrate 201 on which epoxy adhesives are applied and are completely hardened. Therefore, the silicon chip 204 can be mounted on the printed circuit substrate 201. At this time, since the thermal expansion coefficient of polyimide is about 3˜10 ppm/° C., which is similar to the thermal expansion coefficient of silicon of about ˜2.7 ppm/° C., mechanical stress caused by thermal hysteresis can be minimized.

Furthermore, according to the present invention, as the adhesive strength between the epoxy adhesives and the polyimide is stronger than the adhesive strength between the silicon and epoxy adhesive, the problem of delamination often reduced and/or eliminated in many cases.

As described in the above examples, in the structure wherein an integrated circuit chip and the attachment subject are connected to each other by adhesives, the present invention reduces stress and prevents a decrease of adhesive strength caused by differences of the thermal expansion coefficient, and/or differences of properties between the integrated circuit chip and adhesive, so that generation of delamination can be minimized and the interconnection lines between the interior and the exterior of the integrated circuit chip can be protected.

Furthermore, at least one advantage of the present invention is that an interface which is stable in thermal hysteresis and hygroscopicity is formed, thereby improving reliability of the integrated circuit chip and making it possible to implement a large scale package.

While the invention has been shown and described with reference to certain exemplary embodiments thereof, it will be understood by those skilled in the art that various changes in form and details may be made therein without departing from the spirit of the invention and the scope of the appended claims. For example, the type of integrated circuit, interface, and attachment subject are not limited to the examples described herein. Also, with regard to the similarity of the properties, the range of thermal expansion coefficient of the interface layer can be a subset of the range of thermal expansion coefficient of the integrated circuit chip, or the range of thermal expansion coefficient of the integrated circuit chip can be a subset of the range of thermal expansion coefficient of said interface layer, or a range of thermal expansion coefficient of said interface layer and a range of thermal expansion coefficient of the integrated circuit chip may overlap.

What is claimed is:

1. An integrated circuit package comprising:
an attachment subject;
an integrated circuit chip attached to the attachment subject by an adhesive; and
an interface layer disposed between the integrated circuit chip and the adhesive, said interface layer having a thermal expansion coefficient that substantially corresponds to a thermal expansion coefficient of the integrated circuit chip.

2. The integrated circuit package according to claim 1, wherein a range of thermal expansion coefficient of said interface layer is a subset of the range of thermal expansion coefficient of the integrated circuit chip.

3. The integrated circuit package according to claim 1, wherein a range of thermal expansion coefficient of the integrated circuit chip is a subset of the range of thermal expansion coefficient of said interface layer.

4. The integrated circuit package according to claim 1, wherein a range of thermal expansion coefficient of said interface layer and a range of thermal expansion coefficient of the integrated circuit chip overlap.

5. The integrated circuit package according to claim 1, wherein the adhesive comprises an adhesive epoxy.

6. The integrated circuit package according to claim 5, wherein the integrated circuit chip comprises a silicon chip, and the attachment subject comprises a printed circuit substrate.

7. The integrated circuit package according to claim 6, wherein the interface layer has a thermal expansion coefficient ranging from about 3˜5 ppm/° C.

8. The integrated circuit package according to claim 7, wherein the interface layer includes a material having a property of a Young's modulus ranging from about 3˜9 Gpa, a Poisson's ratio ranging from about 0.25˜0.4, and a glass temperature ranging from about 240° C.˜260° C.

9. The integrated circuit package according to claim 7, wherein the interface layer includes at least one of Polyimide, Acrylinitrilebutadienestyrene (ABS), Benzocyclobutene (BCB), Polystyrene (PS), and Polymethylmethacrylate (PMMA).

10. The integrated circuit package according to claim 8, wherein the interface layer includes at least one of Polyimide, Acrylinitrilebutadienestyrene (ABS), Benzocyclobutene (BCB), Polystyrene (PS), and Polymethylmethacrylate (PMMA).

11. The integrated circuit package according to claim 9, wherein the interface layer comprises a polyimide layer and is formed in a thickness of about 2˜7 μm.

12. The integrated circuit package according to claim 10, wherein the interface layer comprises a polyimide layer and is formed in a thickness of about 2˜7 μm.

13. An integrated circuit package having an integrated circuit chip and an attachment subject which are connected with an adhesive, the package comprising an interface layer disposed between the integrated circuit chip and the adhesive and said interface layer having a thermal expansion coefficient that substantially corresponds to the integrated circuit chip.

14. The integrated circuit package according to claim 13, wherein the integrated circuit chip comprises a silicon chip, and the adhesive comprises an adhesive epoxy.

15. The integrated circuit package according to claim 14, wherein the interface layer includes a material having a property of a Young's modulus ranging from about 3˜9 Gpa, a Poisson's ratio ranging from about 0.25˜0.4, and a glass temperature ranging from about 240° C.˜260° C.

16. The integrated circuit package according to claim 13, wherein the interface layer has a thermal expansion coefficient ranging from about 3˜55 ppm/° C.

17. The integrated circuit package according to claim 15, wherein the interface layer has a thermal expansion coefficient ranging from about 3˜55 ppm/° C.

18. The integrated circuit package according to claim 16, wherein the interface layer includes at least one of polyimide, Acrylinitrilebutadienestyrene (ABS), Benzocyclobutene (BCB), Polystyrene (PS), and Polymethylmethacrylate (PMMA).

19. A method of connecting an integrated circuit chip and an attachment subject to each other while interposing an adhesive between the integrated circuit chip and the attachment subject, the method comprising:
applying an adhesive on the attachment subject;
forming an interface layer between the integrated circuit chip and the adhesive, the interface layer having a thermal expansion coefficient similar to a thermal expansion coefficient of the integrated circuit chip; and
connecting the integrated circuit chip to the attachment subject.

20. The method according to claim 19, wherein the integrated circuit chip comprises a silicon chip, the attachment subject comprises a printed circuit substrate, and the adhesive comprises an adhesive epoxy.

21. The method according to claim 20, wherein the interface layer has a thermal expansion coefficient ranging from about 3˜55 ppm/° C.

22. The method according to claim 21, wherein the interface layer includes polyimide.
